(19) United States
(12) Patent Application Publication
(10) Pub. No.: US 2013/0346460 A1
(43) Pub. Date: Dec. 26, 2013

(54) METHOD AND DEVICE FOR FILTERING A SIGNAL AND CONTROL DEVICE FOR A PROCESS

(71) Applicants: Thierry Bruneau, Corroy-le-Grand (BE); Klaus Wendelberger, St. Leon-Rot (DE)

(72) Inventors: Thierry Bruneau, Corroy-le-Grand (BE); Klaus Wendelberger, St. Leon-Rot (DE)

(21) Appl. No.: 13/979,159

(22) PCT Filed: Jan. 10, 2012
(86) PCT No.: PCT/EP2012/050285

§ 371 Date: Sep. 13, 2013

(30) Foreign Application Priority Data
Jan. 11, 2011 (EP) 11150659.8
Feb. 1, 2011 (DE) 10 2011 003 477.3

(51) Int. Cl. H03H 17/02

(52) U.S. Cl. CPC H03H 17/0248
USPC 708/300

(57) ABSTRACT

A method for filtering a signal is proposed. A noisy input signal is continuously examined in order to determine whether the input signal it is within or outside a deadband. The deadband width and the zero point of the deadband are continuously adapted to the noise power of the input signal depending on the time behavior of the input signal and a predefined system time constant. At least one filtered output signal is continuously output, such as a deadband signal, which substantially corresponds to a smoothed input signal.

### CROSS REFERENCE TO RELATED APPLICATIONS

This application is the US National Stage of International Application No. PCT/EP2012/050285 filed Jan. 10, 2012 and claims benefit thereof, the entire content of which is hereby incorporated herein by reference. The International Application claims priority to the European application No. 11150659.8 EP filed Jan. 11, 2011, and claims priority to the German application No. 10 2011 003 477.3 DE filed Feb. 1, 2011, the entire contents of which are hereby incorporated herein by reference.

### FIELD OF INVENTION

The invention relates to a method and a corresponding apparatus for filtering a signal, wherein a noisy input signal is checked continuously to ascertain whether it is within or outside a dead band. The invention furthermore relates to a control device for a process.

### BACKGROUND OF INVENTION

Closed-loop control structures are used for automating industrial processes. In this case, a closed-loop control circuit is composed of
the metrological detection of the actual value of the process variable to be controlled (controlled variable),
the predefinition of a desired value for said process variable (reference variable),
the formation of the control difference (deviation of the controlled variable from the predefined desired value),
the control algorithm (controller), which determines from the control difference how
the actuating element (e.g. valve, flap, motor, ...) should be moved so that the controlled variable approaches the reference variable,
the outputting of the actuating signal to the drive or actuator.

Accordingly, the controlled variable of a component of a technical installation is intended to be kept at a desired value for the controlled variable as well as possible by means of the controller. One problem in closed-loop control processes is generally produced by the noise of the controlled variable, which can be caused by the metrological detection of the controlled variable, a process noise brought about by disturbing influences, or the like.

Undesirable oscillations of the actual value of the controlled variable can be avoided for example with a method which is known from EP 1 490 735 B1. During the operation of a technical installation, constantly the actual value of the controlled variable is determined and the gain factor of a PI controller is varied in a manner dependent on the temporal behavior of the actual value, until the actual value remains within a predefined tolerance band with respect to the desired value. If, in the course of operation, the controlled component is then subject to variation with regard to its dynamic behavior, for example caused by material wear and/or deposition of operating or auxiliary materials of the component, or by aging of parts of the component, the gain factor is varied again only when the actual value of the controlled variable leaves the tolerance band in terms of value. This renewed constant variation of the gain factor takes place again only until the actual value again enters the tolerance band and remains there.

The noise of the controlled variable leads to corresponding noise of the control difference and thus to a continuous excitation of the controller. The latter will then cause the actuating element to continuously perform small actuating movements. However, the noise cannot be eliminated by this actuating movement; it may even also be amplified. The drive itself is subjected to high loading as a result of the continuous, unnecessary movements to and fro, and the wear is correspondingly high.

For this reason, the signal profile for the controlled variable or for the control difference has to be filtered in closed-loop control engineering. At the output of the filter it is necessary to generate a signal which substantially reproduces the profile of the original signal but does not include the rapid, small signal changes.

With regard to the field of signal filtering, the literature contains a multiplicity of methods for example for adaptive filtering. Sophisticated mathematical methods are often described which can be used for smoothing noisy signals, without corrupting the useful information contained in a signal. Such stringent demands are not made, however, in the bulk of the power plant closed-loop control circuits in connection with the filtering of a control difference.

A simple method for realizing such filtering at the input of a controller is to use a dead band, which usually suffices for signal filtering in power plant engineering. Wherever higher-order filter algorithms are required, they are additionally incorporated.

The following function f(x) is defined as the dead band:

f(x)=x−T_{B} for x>a

f(x)=x+T_{B} for x<a

This means (for a=0) that in the case of an input signal x lying within the dead band width or the interval [−T_{B}, T_{B}], the value 0 is output as output signal. Outside this range, the value of the input signal is output in a manner reduced or increased by half the dead band width. A corresponding offset, as expressed here by the constant a, may also be present. Signals which fluctuate around the value 0 can accordingly be smoothed with such a dead band function. As an extension of the dead band function, it is also possible to filter signals which fluctuate around values not equal to zero (e.g. here a).

In control systems, controller components are usually equipped with such dead band functions as standard. The control difference, which fluctuates around the value zero on account of the fact that the controlled variable is controlled to its desired value, is then switched to the dead band. If the control difference varies only within the dead band that has been set, by definition the value zero will always be present at the output of the filter and the controller is therefore not excited. Only relatively large changes in the control difference come through. The influence of the noise is thus eliminated.

The problem area consists, then, in the fact that the width of the dead band has to be set individually for each closed-loop control circuit. If the dead band is too small, part of the noise still comes through. If it is too large, the controller reacts too late to control differences that actually occur. The controlled-variable signal therefore has to be examined and the width of the noise has to be determined in order to be able to correctly set the dead band. By way of example, there are approximately 200-300 controllers in a power plant process. The setting of all the dead bands is therefore a very complex operation. This holds true particularly when it is taken into consideration that the noise width can vary e.g. as a function of the present operating point of the installation, over time as a result of variation of the external disturbing influences or as a result of wear phenomena or the like. The set values for the dead bands herefore have to be multiply readjusted, under certain circumstances. This is very laborious since the setting of the dead bands in power plant closed-loop control is nowadays effected manually by an engineer in the context of process-engineering start-up and optimization.

### SUMMARY OF INVENTION

Therefore, the object of the present invention is to specify a method and a corresponding apparatus for signal filtering with the aid of a dead band which allows a fully automatic adaptation of the dead band in the course of operation, wherein a signal which substantially reproduces the profile of the original signal but does not include the rapid, small signal changes is intended to be present after the signal filtering. Furthermore, the intention is to specify an improved control device by means of which the above-described disadvantages from the prior art are overcome.

The object is achieved according to the invention by means of a method and a corresponding apparatus wherein a noisy input signal is checked continuously to ascertain whether it is within or outside a dead band. In this case, in contrast to the prior art, the dead band width is not fixedly predefined or set beforehand, but rather is varied in the course of operation in a manner dependent on the temporal behavior of the input signal and a chosen system time constant. Moreover, the zero point of the dead band function is also varied and thus set by means of the algorithm according to the invention. An automatic online adaptation of the dead band width and of the “offset” (of the zero point of the dead band function) is achieved in this way. This advantageously involves a self-learning algorithm which-once initiated-always proceeds concomitantly for example in a technical installation. The filtered output signal substantially corresponding to the smoothed input signal is likewise output online. The output signal substantially reproduces the profile of the original signal as desired, but does not include the rapid, small signal changes.

In one advantageous configuration of the invention, the dead band width is increased by a factor if the input signal has passed through the dead band a specific number n times within a first, preferably short, time duration. In contrast to the patent EP 1490735, where a change in the parameter to be adapted (in that case the gain factor of a controller) by a factor is triggered when the monitored variable (in that case actual value) passes through the dead band once, here it is advantageously possible to predefine the number n of dead band passes. The parameter change (here the adaptation of the dead band width) is carried out only if the monitored variable (here the input signal) has passed through the dead band at least n times. More flexibility with regard to the setting of the dead band width is obtained in this way. The daptive filtering can be influenced particularly advantageously by means of the number n of dead band passes.

In a further advantageous configuration of the invention, the dead band width is decreased continuously over time if the input signal is within an inner range of the dead band, and stays there, during a second, preferably long, time duration.

It is particularly advantageous if, alongside a first filtered output signal such as a dead band signal, for example, a second filtered output signal such as, for example, a dead band signal corrected by the average value of the noise is output. As a result, the user acquires additional information which may be advantageous in the operation of a technical installation. The outputting of further output signals such as, for example, a maximum value still just lying within the dead band, or a corresponding minimum value, is likewise conceivable and shows the performance of the algorithm according to the invention.

Advantageously, the count of the dead band passes is reset to zero if the time period between a maximum and minimum of the input signal is greater than a predefined maximum half period duration. In this way, noise is advantageously distinguished from “genuine” signal movement.

One particularly advantageous possibility for use of the method according to the invention is in closed-loop control engineering. A control device comprising an apparatus for filtering a signal with the aid of an adaptive dead band in the course of operation increases the quality of the closed-loop control in a technical installation, and thus also the process underlying the installation. It is not just in the power plant field that there is the trend toward fully automatic adaptation of closed-loop controls of the individual components. The closed-loop control device with adaptive, fully automatic signal filtering in the course of operation of an installation is universally useable and is suitable for obtaining optimum and installation-preserving closed-loop control results.

In a further advantageous configuration of the invention, the control device consists of an apparatus for adaptive signal filtering according to the invention and, connected downstream, a PI controller having an adaptively adjustable gain factor. In this embodiment, in particular, oscillations of the input signal are intended to be avoided and the controller is intended to be set such that an optimum control quality is obtained, that is to say that the controlled variable follows its desired value as precisely as possible. The combination of both components affords multiple advantages: fewer costs arise, owing to the fact that work previously performed manually now proceeds automatically. The closed-loop controls exhibit less wear and do not deteriorate over time. An installation containing the abovementioned control components can be optimized more rapidly and is therefore also available again more rapidly.

### BRIEF DESCRIPTION OF DRAWINGS

The invention is explained in greater detail below on the basis of exemplary embodiments illustrated in the drawings. In the figures:

FIG. 1 shows a graphical representation of an exemplary profile of the input signal, wherein the profile of the dead band and the profile of the two output signals are likewise depicted,

FIG. 2 shows a further exemplary temporal profile of the input signal, this profile being enlarged in terms of its scale, and

FIG. 3 shows a control device comprising an apparatus for filtering according to the present invention.

### DETAILED DESCRIPTION OF INVENTION

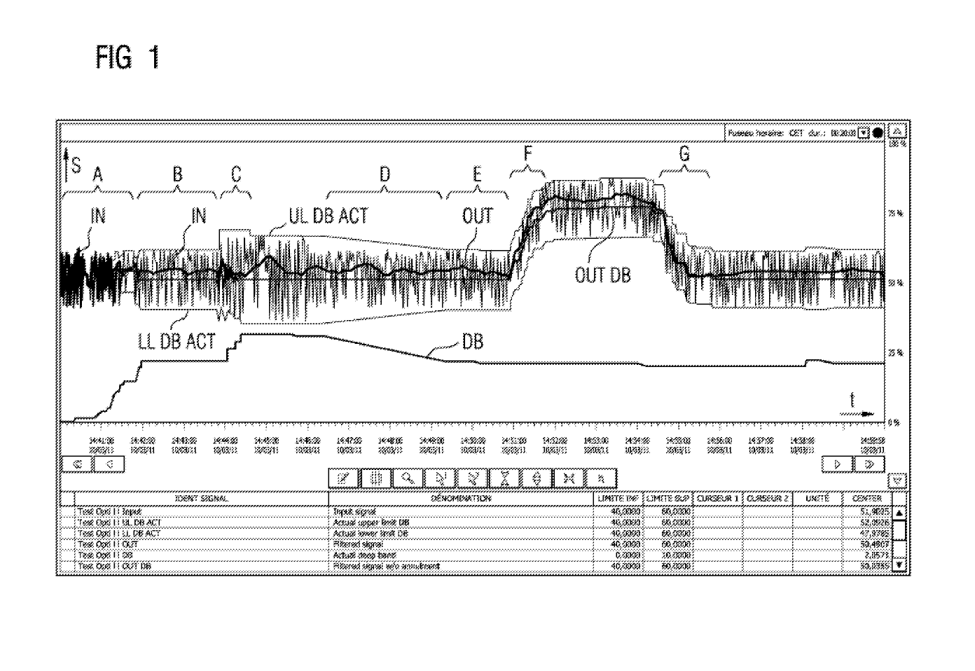

FIG. 1 comprises a computer printout of a screenshot of a control system in which the method according to the invention is implemented. A graphical representation of signal profiles can be seen in the upper part of FIG. 1, and the lower part comprises a table with further indications concerning the signal profiles represented. The designations and descriptions of the signals represented, and also the values and limits thereof, are noted there.

The description of the exemplary embodiment mainly refers to the signal profiles represented in the upper segment of the figure, wherein the time t (here as the time of day in minute intervals) is plotted on the abscissa and the signal profiles S are plotted on the ordinate. The input signal IN has high-frequency noise. This can be an arbitrary process signal, a control difference or the pure actual value of a measurement signal.

In the context of the filter algorithm according to the invention, then, continuously (online) in the course of operation of an installation, proceeding from the noisy input signal IN and other predefined or predefinable values, at least one filtered output signal is calculated, immediately output and represented.

By way of example, the start value zero is predefined for the dead band width DB. Alternatively, a start value greater than zero would also be possible. The learning algorithm is then enabled. It then takes a while until the algorithm has learned to a sufficient extent until the noise has gone (see region A in FIG. 1). According to the present invention, the dead band width is adaptively adapted to the signal profile, that is to say that the dead band width is continuously varied in a manner dependent on the temporal behavior of the input signal IN. The present total value DB of the dead band is in each case plotted directly above the abscissa.

The dead band can be arranged for example symmetrically around the average value of the minima and maxima of the amplitude of the input signal and proceeds similarly to an envelope directly in the vicinity of the minima and maxima of the amplitude of the input signal. The upper limit values of the dead band are designated by UL DB, and a respective present value is called UL DB ACT. The lower limit values of the dead band are designated by LL DB, and a respective present value is called LL DB ACT.

As soon as a dead band width DB has been defined, a check is made to determine whether the input signal lies within or outside the dead band with its present width (region B of FIG. 1). If the value lies within the present dead band width, for example an average value of the preceding oscillation amplitudes is output as the output signal. In the exemplary embodiment illustrated in FIG. 1, the output signal OUT DB is the output signal of the dead band. If the input signal is a control difference, for example, then the value zero is output for OUT DB, which means that the input signal is within the present dead band width. If the noise exhibits a high degree of asymmetry, that is to say if the average value of the input signal over time does not lie exactly centrally between the maximum and the minimum of the amplitude, this can be read on the basis of a second output signal OUT. In this exemplary embodiment, the average value of the noisy signal over time is reproduced correctly by means of the signal OUT. The signal profile for the signal OUT is accordingly not as smooth as the profile of the signal OUT DB, since here the filter effect is somewhat reduced by virtue of the signal fluctuations being taken into consideration to a greater extent. Nevertheless, here as well the high oscillation frequencies are no longer present.

FIG. 1 shows clearly that the dead band width DB is varied continuously over time. It is evident at the very first glance that the dead band width is automatically increased or decreased and is placed like a tube around the amplitude extrema of the input signal and thus only follows “genuine” fluctuations of the input signal. “Genuine” fluctuation means that here the average value of the maxima and minima of the input signal changes.

In order to be able to vary the dead band width adaptively, firstly a time constant has to be predefined in order that time periods or time durations can be defined and in order that rates of change of the input signal can also be determined A so-called system time constant thus describes the dynamic system behavior and is dependent on the overall system considered. In the power plant field, a temperature control system would have system time constants of between 30 and 60 s, for example, while a pressure control system would comprise time constants of between 5 and 10 s. By means of these time constants, the signal noise can be distinguished from “genuine” signal changes. A temperature cannot change multiply for example within a time duration of 5 s. If the measured temperature value exhibits such behavior, however, then a signal noise rather than a genuine signal change must be involved.

As an example, a time duration of 20 s will be assumed here as system time constant. If multiple oscillations of the input signal can be observed within this time duration, then this involves noise in the case of a measured temperature value, but a rapid signal change in the case of a measured pressure value. Accordingly, even terms such as “long” or “short” time durations can be quantified on the basis of the system time constant.

According to the method according to the invention, the dead band width is continuously decreased if the input signal IN already stays within an inner range of the dead band within a second time duration and is still there, wherein the second time duration is determined by the system time constant and the width of the inner range is predefined. In the case of the second time duration, a comparatively long time duration that is greater than the system time constant is assumed here.

The width of the inner range of the dead band is intended to be defined on a case-by-case basis here. As an example, a width of 95% of the total width of the dead band shall be assumed for the inner range. The input signal is accordingly observed continuously to ascertain whether it lies within or outside a dead band with a width reduced by 5% in this case. This dead band will be designated hereinafter as the 95% dead band. If the input signal then stays within said 95% dead band for a long time, the dead band is decreased continuously. This is clearly evident in the region D in FIG. 1. Over a time period of almost 3 minutes, the oscillations of the input signal proceed within the dead band limits depicted. The dead band width accordingly varies continuously. The rate of reduction of the dead band width is determined in a manner dependent on the system time constant. The slower the system, the more slowly the dead band is decreased as well. The rate of reduction of the dead band width is additionally reduced, the smaller the dead band already is. The decreasing of the dead band width is stopped if the input signal IN leaves the inner range of the dead band (here the 95% dead band) again and/or the dead band width reaches a lower limit value (see region E in FIG. 1).

In the regions F and G in FIG. 1, the average value of the input signal conspicuously changes by approximately 25%. The performance of the algorithm according to the invention becomes clear within these regions. The dead band follows the input signal and is adapted thereto. The zero point is shifted in accordance with the signal profile since a “genuine” signal change is present. In these regions, no significant adaptation of the dead band width is necessary, since the noise power does not change.

According to the method according to the invention, the dead band width is increased by a factor if the input signal IN crosses the dead band limits n times alternately upward and downward within a first time duration, wherein the number n of passes is predefined by the dead band limits, and the first time duration is determined by the system time constant. The first time duration is a comparatively short time duration. Afterward, the dead band width is increased by a factor each further time when the input signal passes through the dead band in a short time. The increasing of the dead band width is stopped if the input signal no longer passes through the dead band within a short time duration or the dead band width reaches an upper limit value. The count of the dead band passes on the basis of the parameter n is reset to zero if the input signal remains within the dead band again.

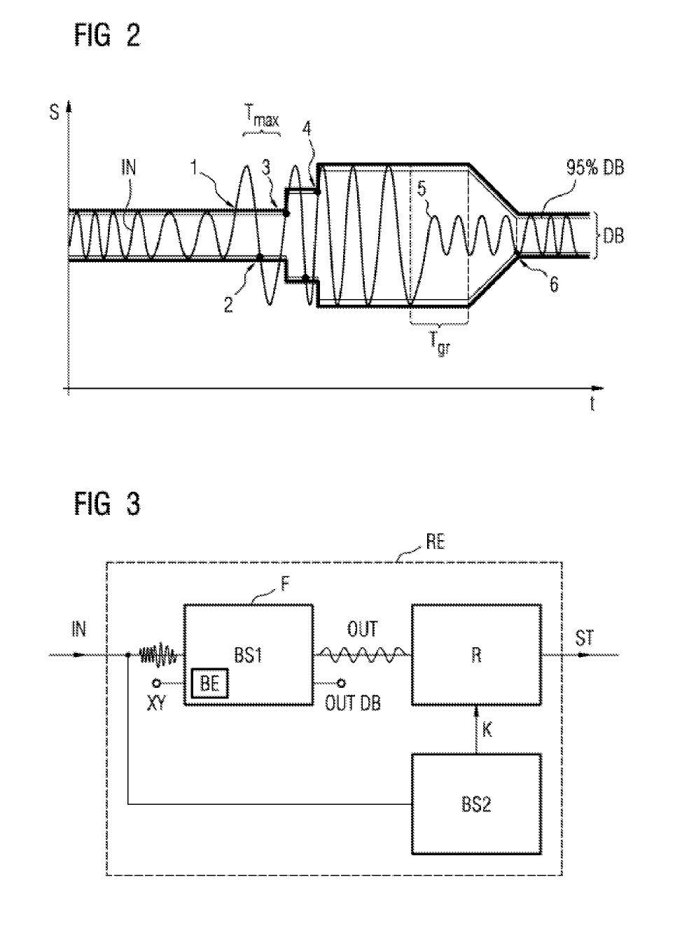

One example of the case of the increasing of the dead band width is illustrated in FIG. 2. Here a portion from the region C from FIG. 1 has been increased.

At the beginning of the signal profile, the input signal IN remains within the upper and lower dead band limits, which are represented here by thick lines. Furthermore the 95% dead band is identified in each case by a thin line. The signal IN then emerges from the dead band at the location 1 and passes through the dead band DB for the first time at the location 2. The number of dead band passes which are intended to increase the dead band width shall be defined here by n=2. The signal IN then passes through the dead band 2 times alternately downward and upward within a short time duration. The time duration Tmax was defined beforehand as the maximum time for a pass. As can be discerned, the signal IN passes through the dead band limits within a shorter time duration (T<Tmax). Thus, both conditions that result in the dead band width being increased by a factor are met at point 3. Two further passes of the input signal IN through the dead band take place, as a result of which the dead band width is increased by a factor again at point 4. The signal subsequently remains within the dead band limits until it assumes a smaller amplitude at point 5. The signal then remains within the 95% dead band for a relatively long time period Tgr. After this second, relatively long time duration, the dead band is decreased continuously until the signal crosses the 95% dead band at point 6. Since the signal IN then remains within the outer dead band depicted by a thick line, the dead band width is maintained.

FIG. 3 shows an apparatus F according to the invention for filtering a signal IN with a control device R connected downstream. The input signal IN can be applied to a first input of the apparatus F. Furthermore, at least one second input XY is present in order to receive further parameters or values. Via such an input, for example the system time constant or the number n of passes of the input signal through the dead band limits which are necessary for increasing the dead band width are fed to the filter apparatus F. The filter apparatus F comprises a calculation unit BE, by means of which the adaptive filtering of the input signal according to the present invention is carried out. At least one signal output for outputting the filtered output signal OUT is present at the output of the filter apparatus F. At least one second output for a second output signal OUT DB is optionally provided. At least one of the outputs illustrated can be connected to a controller R. The controller R serves for the closed-loop control of at least one component of a technical installation and can be designed as a PI controller, for example.

In one embodiment variant, the controller R can then be optimized by a further component BS2. An increased control quality is achieved by means of a combination of the filter apparatus F according to the invention (or else component 1, BS1) with a PI controller R which is adapted in accordance with EP 1 490 735 B1. During the operation of a technical installation, in component 2 BS2 constantly the actual value of the controlled variable is determined and the gain factor K and a reset time of a PI controller are varied in a manner dependent on the temporal behavior of the actual value until the actual value remains within a predefined tolerance band with respect to the desired value. The optimized gain factor K and a reset time are fed to the controller R, which outputs an actuating signal ST, which in turn influences the controlled variable.

In this way, a combination of the adaptive filtering of an input signal and the adaptive setting of the gain factor of a PI controller is achieved, which results in an increased control quality. The combination of the components BS1 and BS2 is realized as the control device RE. A combination of the adaptive filter according to the invention with other controllers and control devices is likewise conceivable.

1.-10. (canceled)

11. A method for filtering a signal, comprising:
continuously checking a noisy input signal to ascertain whether the input signal is within or outside a dead band having a dead band width around a zero point,
wherein the dead band width and the zero point of the dead band are varied during an operation depending on a temporal profile of the input signal, and
wherein online at least one filtered output signal corresponding to a dead band signal and substantially corresponding to a smoothed input signal is output.

12. The method as claimed in claim 11, wherein the temporal profile of the input signal is quantified based on a predefined system time constant.

13. The method as claimed in claim 12, further comprising:
increasing the dead band width by a factor if the input signal has passed through the dead band n times alternately upward and downward within a first time duration, and
stopping increasing the dead band width if the input signal no longer passes through the dead band within the first time duration or the dead band width reaches an upper limit value,
wherein the number n of passes is predefined and the first time duration is determined by the system time constant.

14. The method as claimed in claim 12, further comprising:
decreasing the dead band width by a factor if the input signal stays within an inner range of the dead band within a second time duration, and
stropping decreasing the dead band width if the input signal leaves the inner range of the dead band again and/or the dead band width reaches a lower limit value,
wherein the width of the inner range is predefined and the second time duration is determined by the system time constant.

15. The method as claimed in claim 11, wherein a count of the input signal passes through the dead band is reset to zero if the input signal remains in the dead band for a predefined time duration.

16. The method as claimed in claim 11, wherein the at least one filtered output signal is output online.

17. A control device for a process, comprising:
a controller; and
an apparatus connected upstream of an input of the controller for filtering a signal, wherein the apparatus comprises:
at least one signal input for receiving a noisy input signal;
a further input for applying parameters and/or measured values to the apparatus;
a calculation unit for processing the input signal by a method as claimed in claim 11;
at least one signal output for outputting a filtered output signal; and
a further output for outputting a further output signal;
wherein a controlled variable is continuously detected as actual value,
wherein a desired value for the controlled variable is predefined,
wherein a difference between the actual value and the desired value is fed to the controller, and
wherein the difference influences the controlled variable by an actuating signal.

18. The control device as claimed in claim 17, wherein the controller is a PI controller comprising parameters of a gain factor and a reset time which are adaptively adjustable.

19. A computer program storage medium storing a computer program executable on a computer, comprising:
a program code for implementing a method as claimed in claim 11.
